(19) United States
(12) Patent Application Publication
(10) Pub. No.: US 2026/0082708 A1
(43) Pub. Date: Mar. 19, 2026

(54) SOLAR CELL, MULTIJUNCTION SOLAR CELL, SOLAR CELL MODULE, SOLAR POWER GENERATION SYSTEM, AND METHOD FOR MANUFACTURING SOLAR CELL

(71) Applicant: KABUSHIKI KAISHA TOSHIBA, Kawasaki-shi (JP)

(72) Inventors: Kanta Sugimoto, Yokohama Kanagawa (JP); Takuo Kikuchi, Kamakura Kanagawa (JP)

(21) Appl. No.: 19/308,900

(22) Filed: Aug. 25, 2025

(30) Foreign Application Priority Data
Sep. 13, 2024 (JP) 2024-159155

(51) Int. Cl. H10F 10/172; H10F 19/20; H10F 71/00; H10F 77/20

(52) U.S. Cl. CPC H10F 10/172; H10F 19/20; H10F 71/1385; H10F 77/244

(57) ABSTRACT

According to one embodiment, a solar cell including a transparent first electrode, an n-type layer, a light absorption layer that contains an inorganic material, and a second electrode is provided. The n-type layer is present between the first electrode and the light absorption layer. The light absorption layer is present between the n-type layer and the second electrode. The first electrode has a gap penetrating the first electrode. The n-type layer, the light absorption layer, and the second electrode are each partially included in the gap, and a part of the n-type layer, a part of the light absorption layer, and a part of the second electrode are arranged in this order in the gap.

### CROSS-REFERENCE TO RELATED APPLICATION

This application is based upon and claims the benefit of priority from prior Japanese Patent Application No. 2024-159155, filed Sep. 13, 2024, the entire contents of which are incorporated herein by reference.

### FIELD

The present disclosure relates to a solar cell, multijunction solar cell, solar cell module, solar power generation system, and method for manufacturing a solar cell.

### BACKGROUND

One of new solar cells is a solar cell using cuprous oxide (Cu₂O) in a light absorption layer. Cu₂O is a wide-gap semiconductor. Since Cu₂O is a safe and inexpensive material made of copper and oxygen, which are abundantly present on Earth, it is anticipated to be able to realize a highly efficient low-cost solar cell.

In addition, there is a multijunction (tandem) solar cell as a highly efficient solar cell. The tandem solar cell can use a cell having high spectral sensitivity for each wavelength band, and thus can have higher efficiency than in the case of single junction. As the top cell of the tandem solar cell, a Cu₂O solar cell having a wide band gap of the light absorption layer and high translucency can be suitably used.

### BRIEF DESCRIPTION OF THE DRAWINGS

FIG. 1 is a cross-sectional conceptual view illustrating an example of a solar cell according to an embodiment.

FIG. 2 is a cross-sectional conceptual view illustrating an example of a conventional solar cell.

FIG. 3 is a cross-sectional conceptual view illustrating another example of a conventional solar cell.

FIG. 4 is a cross-sectional conceptual view illustrating an example of an array cell structure of the solar cell according to the embodiment.

FIG. 5 is a cross-sectional conceptual view illustrating a part of an example of manufacturing the solar cell according to the embodiment.

FIG. 6 is a cross-sectional conceptual view illustrating a part of the example of manufacturing the solar cell according to the embodiment.

FIG. 7 is a cross-sectional conceptual view illustrating a part of the example of manufacturing the solar cell according to the embodiment.

FIG. 8 is a cross-sectional conceptual view illustrating a part of the example of manufacturing the solar cell according to the embodiment.

FIG. 9 is a cross-sectional conceptual view illustrating a part of the example of manufacturing the solar cell according to the embodiment.

FIG. 10 is a cross-sectional conceptual view illustrating a part of the example of manufacturing the solar cell according to the embodiment.

FIG. 11 is a cross-sectional conceptual view illustrating a part of the example of manufacturing the solar cell according to the embodiment.

FIG. 12 is a cross-sectional conceptual view illustrating a part of the example of manufacturing the solar cell according to the embodiment.

FIG. 13 is a cross-sectional conceptual view illustrating a part of manufacturing an example of a conventional solar cell.

FIG. 14 is a cross-sectional conceptual view illustrating an example of a multijunction solar cell according to an embodiment.

FIG. 15 is a cross-sectional conceptual view illustrating an example of a conventional multijunction solar cell.

FIG. 16 is a perspective view conceptually illustrating an example of a solar cell module according to an embodiment.

FIG. 17 is a cross-sectional conceptual view illustrating the example of the solar cell module according to the embodiment.

FIG. 18 is a conceptual view illustrating an example of a solar power generation system according to an embodiment.

### DETAILED DESCRIPTION

According to one embodiment, a solar cell including a transparent first electrode, an n-type layer, a light absorption layer that contains an inorganic material, and a second electrode is provided. The n-type layer is present between the first electrode and the light absorption layer. The light absorption layer is present between the n-type layer and the second electrode. The first electrode has a gap penetrating the first electrode. The n-type layer, the light absorption layer, and the second electrode are each partially included in the gap, and a part of the n-type layer, a part of the light absorption layer, and a part of the second electrode are arranged in this order in the gap.

According to another embodiment, provided is a multijunction solar cell including a first solar cell and a second solar cell that includes a second light absorption layer having a band gap smaller than a band gap of a first light absorption layer of the first solar cell. The first solar cell is the solar cell according to the above embodiment. The second electrode is a transparent electrode.

According to another embodiment, provided is a solar cell module comprising the solar cell according to the above embodiment.

According to another embodiment, provided is a solar power generation system including the solar cell module according to the above embodiment.

In addition, there is provided a method for manufacturing a solar cell including a transparent first electrode, an n-type layer, a light absorption layer that contains an inorganic material, and a second electrode. In the solar cell, the n-type layer is present between the first electrode and the light absorption layer, and the light absorption layer is present between the n-type layer and the second electrode. The first electrode has a gap penetrating the first electrode. The n-type layer, the light absorption layer, and the second electrode are each partially included in the gap, and a part of the n-type layer, a part of the light absorption layer, and a part of the second electrode are arranged in this order in the gap. The method includes forming an oxide transparent conductive film on a transparent substrate, obtaining the first electrode by partially removing the oxide transparent conductive film, forming an n-type semiconductor film on the first electrode and the transparent substrate exposed through the gap, obtaining the n-type layer by removing a portion of the n-type semiconductor film in contact with a side surface of the first electrode located on one side of the gap and a part of a portion of the n-type semiconductor film in contact with an upper surface of the first electrode adjacent to the side surface, forming an inorganic material film on the n-type layer, on the transparent substrate exposed through the gap, and on the first electrode exposed, obtaining the light absorption layer by removing portions of the inorganic material film in contact with the side surface and the upper surface, and obtaining the second electrode by forming another conductive film on the light absorption layer, on the transparent substrate exposed through the gap, and on the first electrode exposed. Hereinafter, the solar cell according to the embodiment and manufacturing method thereof will be described with reference to the drawings. The same reference signs are applied to practically equal components throughout the embodiments, and in some cases, explanations thereof may be omitted in part. Each drawing is schematic, and therefore, relationships between thicknesses and planar dimensions, ratios among thicknesses of each section, and the like may differ from those in reality. Terms within the explanation indicating directions such as up and down indicate relational directions in the case where the surface of the transparent substrate onto which the electrodes and photoelectric conversion member are provided, as described later, is turned face-up, unless explicitly indicated otherwise in particular; they may differ from a direction in actual use based on the direction of gravitational acceleration.

### First Embodiment

According to a first embodiment, a solar cell is provided. The solar cell includes a transparent first electrode, an n-type layer, a light absorption layer, and a second electrode. The first electrode has a gap penetrating the first electrode. The n-type layer is present between the first electrode and the light absorption layer. The light absorption layer contains an inorganic material and is present between the n-type layer and the second electrode. The n-type layer, the light absorption layer, and the second electrode are each partially included in the gap. A part of the n-type layer, a part of the light absorption layer, and a part of the second electrode are arranged in this order in the gap.

The solar cell is a photoelectric conversion device capable of exhibiting excellent power conversion efficiency (PCE). The reason why excellent conversion efficiency can be exhibited will be described below.

### <Solar Cell>

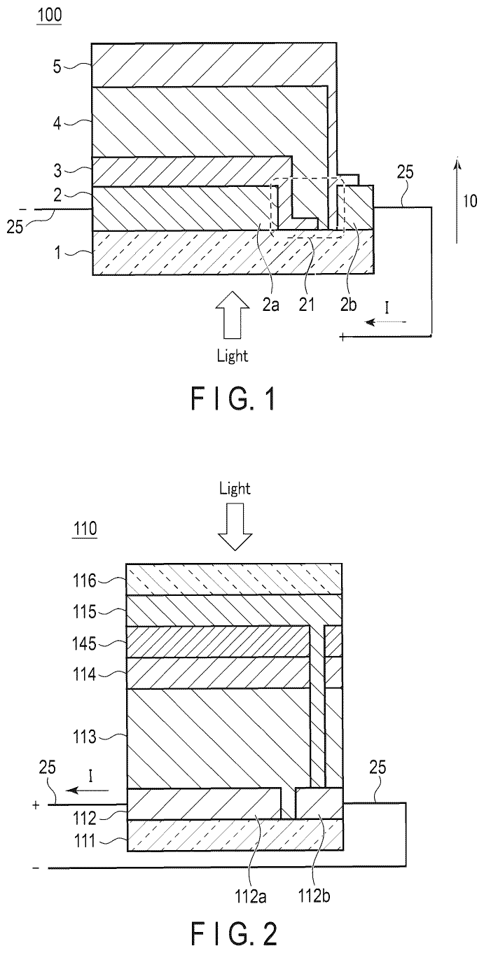

FIG. 1 shows a schematic cross-sectional view illustrating an example of the solar cell. A solar cell 100 illustrated in the figure includes: a transparent substrate 1; and a transparent n-type first electrode 2 having a layer shape, an n-type layer 3, a light absorption layer 4, and a p-type second electrode 5 having a layer shape, which are sequentially stacked on the transparent substrate 1. Although an example is not illustrated in the figure, an intermediate layer (buffer layer) may be provided between the first electrode 2 and the n-type layer 3. The first electrode 2 is provided with a gap 21 which penetrates the first electrode 2 in a first direction 10 that is a thickness direction thereof and along a stacking direction of the respective members, and the first electrode 2 is divided into a negative-side first electrode piece 2a and a positive-side first electrode piece 2b due to the first electrode 2 having the gap 21.

A main portion of the n-type layer 3 is present between the first electrode 2 and the light absorption layer 4 along the first direction 10, and is present along a principal surface of the first electrode 2. Another part of the n-type layer 3 enters the gap 21 and covers a side surface of the negative-side first electrode piece 2a. The part of the n-type layer 3 entering the gap 21 reaches a surface of the transparent substrate 1. Similarly, a main portion of the light absorption layer 4 is present between the n-type layer 3 and the second electrode 5 along the first direction 10, and is present along a principal surface of the n-type layer 3. Another part of the light absorption layer 4 enters the gap 21, and covers the part of the n-type layer 3 entering the gap 21. In the example illustrated in the figure, a part of the light absorption layer 4 entering the gap 21 reaches the surface of the transparent substrate 1. The light absorption layer 4 need not reach the transparent substrate 1. Similarly, a main portion of the second electrode 5 is present along a principal surface of the light absorption layer 4, but another part thereof enters the gap 21, and covers the part of the n-type layer 3 entering the gap 21 and a side surface of the positive-side first electrode piece 2b. Further, the part of the second electrode 5 entering the gap 21 reaches the surface of the transparent substrate 1. In this way, the gap 21 of the first electrode 2 is filled with the part of each of the n-type layer 3, the light absorption layer 4, and the second electrode 5 entering the gap. The part of each of the n-type layer 3, the light absorption layer 4, and the second electrode 5 in the gap 21 is arranged in this order from the negative-side first electrode piece 2a toward the positive-side first electrode piece 2b. The shape of the principal surface of each member is not limited to a flat surface as illustrated in the figure, and may be, for example, a curved surface.

The exemplified solar cell 100 has a superstrate structure, and its surface on the transparent substrate 1 side is a light incident surface. Most of light incident from the transparent substrate 1 side passes through the transparent substrate 1 and main portions of the first electrode 2 and the n-type layer 3, and is at least partially absorbed by the light absorption layer 4. Specifically, light is absorbed at a position close to a pn junction region in the light absorption layer 4, that is, in the vicinity of an interface between the n-type layer 3 and the light absorption layer 4, and electron-hole pairs are generated. Namely, the n-type layer 3 and the light absorption layer 4 constitute a photoelectric conversion unit, and free carriers (free electrons and free holes) are generated in a pn junction region thereof. Next, the dissociated free electrons and free holes diffuse respectively to the negative-side first electrode piece 2a of the first electrode 2, which is an n-electrode, and the second electrode 5, which is a p-electrode, along a direction of potential gradient. The negative-side first electrode piece 2a serves as an anode, the positive-side first electrode piece 2b electrically connected to the second electrode 5 serves as a cathode, and current I flows by connecting an energization path 25 between these electrode pieces. Therefore, power can be extracted outside the solar cell 100 through the energization path 25. In this way, for example, light energy of sunlight can be converted into electric power, that is, solar power generation can be performed. The light which can be converted into electric power by photoelectric conversion is not limited to sunlight.

In the solar cell 100, a part of the n-type layer 3, a part of the p-type light absorption layer 4, and a part of the p-type second electrode 5 are arranged inside the gap from the negative-side first electrode piece 2a toward the positive-side first electrode piece 2b, so that a buffer structure of a band gap is formed between the negative-side first electrode piece 2a and the positive-side first electrode piece 2b. As a result, it is possible to suppress occurrence of recombination of electrons and holes before electric power is extracted through the energization path 25. In addition, it is possible to avoid current leakage that may occur when the gap 21 is filled with only the n-type semiconductor or only the p-type semiconductor. Therefore, the solar cell 100 can exhibit excellent conversion efficiency.

Moreover, for example, when the solar cell is used as a top cell of a multijunction solar cell, the solar cell is joined to a bottom cell at a side of the second electrode, which is a rear electrode with respect to the light incident surface. Since a sealing glass substrate or the like is not required to be provided on the second electrode side, the number of glass substrates or the like included in the top cell can be limited to one transparent substrate on the first electrode side. Therefore, a material-saving and lightweight solar cell can be realized.

For example, when the solar cell is not used as a top cell in a multijunction solar cell but is used alone without being stacked with another solar cell, the second electrode need not have translucency. In this case, for example, the second electrode can be formed of a metal material or an alloy material having excellent electrical conductivity. This allows reduction of electrical resistance of the second electrode itself and electrical resistance at a connection interface between the positive-side first electrode piece and the second electrode extending from an upper part to a lower part of the solar cell.

Next, the above-described solar cell according to the embodiment is compared with a conventional solar cell.

FIG. 2 shows a conceptual view illustrating an example of a conventional solar cell. A solar cell 110 illustrated in the figure includes a substrate 111, and stacked sequentially thereon, a p-electrode 112, a light absorption layer 113, an n-type layer 114, a buffer layer 145 (for example, a zinc tin oxide (ZTO) film), a transparent n-electrode 115, and a sealing substrate 116. The p-electrode 112 is divided into a positive-side p-electrode piece 112a and a negative-side p-electrode piece 112b. A gap between the positive-side p-electrode piece 112a and the negative-side p-electrode piece 112b is filled with a part of the light absorption layer 113. A part of the n-electrode 115 penetrates the n-type layer 114, the buffer layer 145, and the light absorption layer 113, extending from an upper part to a lower part of the solar cell 110, thereby being electrically connected to the negative side p-electrode piece 112b located at the lower part.

The solar cell 110 has a substrate structure, and its surface on a rear side of the solar cell 110 with respect to the substrate 111, that is, its surface on the sealing substrate 116 side is a light incident surface. Light incident from the sealing substrate 116 side passes through the sealing substrate 116, the n-electrode 115, the buffer layer 145, and the n-type layer 114, then becomes absorbed by the light absorption layer 113, whereby electron-hole pairs are generated. The dissociated free electrons and free holes diffuse respectively to the n-electrode 115 and the positive-side p-electrode piece 112a of the p-electrode 112. The positive-side p-electrode piece 112a serves as a cathode, and the negative-side p-electrode piece 112b electrically connected to the n-electrode 115 serves as an anode. Current I flows by connecting an energization path 25 between these electrode pieces, and power can be extracted outside of solar cell 110.

In this conventional solar cell 110, only the light absorption layer 113 is interposed between the positive-side p-electrode piece 112a and the negative-side p-electrode piece 112b, and thus the above-described effect of suppressing recombination of electrons and holes, which is achieved by the solar cell 100 according to the embodiment, is not exhibited. In addition, a glass substrate is typically used for both the substrate 111 and the sealing substrate 116 positioned at the upper and lower parts of the solar cell 110, and so, the number of glass substrates included is two. Therefore, a large amount of material is required, and the thickness and weight are increased. In addition, a transparent material is required to be used for the n-electrode 115 not only when a multijunction solar cell is formed together with another solar cell, but even when the solar cell 110 is used alone, and thus, the n-electrode 115 which penetrates the solar cell 110 in the stacking direction cannot be replaced with a material having excellent electrical conductivity such as metal, whereby a resistance component cannot be reduced.

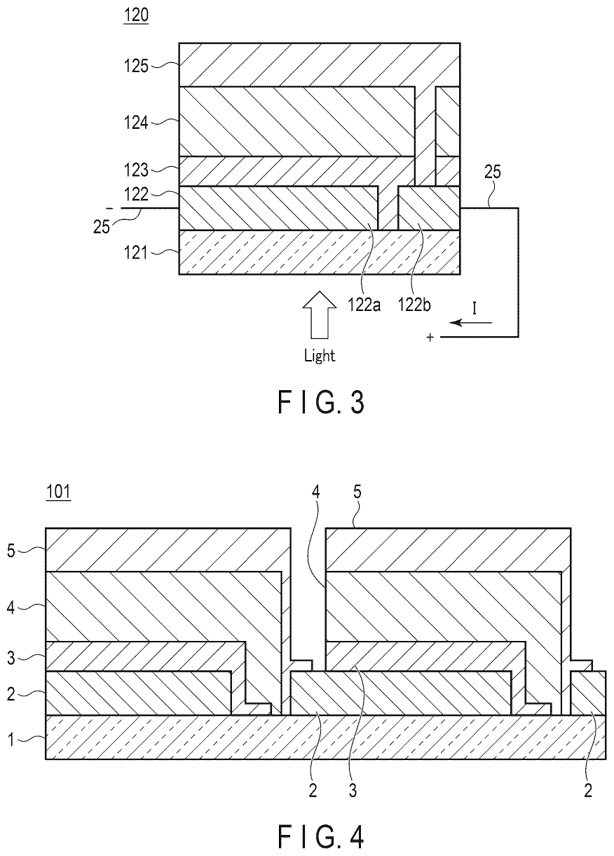

FIG. 3 shows a conceptual view illustrating another example of a conventional solar cell. A solar cell 120 illustrated in the figure includes a transparent substrate 121 and sequentially stacked thereon, a transparent n-electrode 122, an n-type layer 123, a light absorption layer 124, and a p-electrode 125. The n-electrode 122 is divided into a negative-side n-electrode piece 122a and a positive-side n-electrode piece 122b. A gap between the negative-side n-electrode piece 122a and the positive-side n-electrode piece 122b is filled with a part of the n-type layer 123. A part of the p-electrode 125 penetrates the light absorption layer 124 and the n-type layer 123, extending from an upper part to a lower part of the solar cell 120, thereby being electrically connected to the positive side n-electrode piece 122b located at the lower part.

The solar cell 120 has a superstrate structure, and its surface on the transparent substrate 121 side is a light incident surface. Light incident from the transparent substrate 121 side passes through the transparent substrate 121, the n-electrode 122, and the n-type layer 123, and is at least partially absorbed by the light absorption layer 124. Specifically, light is absorbed at a position close to a pn junction region in the light absorption layer 124, that is, in the vicinity of an interface between the n-type layer 123 and the light absorption layer 124, and electron-hole pairs are generated. The dissociated free electrons and free holes diffuse respectively to the n-electrode 122 and the negative-side n-electrode piece 122a of the n-electrode 122, respectively. The negative-side n-electrode piece 122a serves as an anode, and the positive-side n-electrode piece 122b electrically connected to the p-electrode 125 serves as a cathode. Current I flows by connecting an energization path 25 between these electrode pieces, and power can be extracted outside the solar cell 120.

In this conventional solar cell 120, only the n-type layer 123 is interposed between the negative-side n-electrode piece 122a and the positive-side n-electrode piece 122b, and thus the above-described effect of suppressing recombination of electrons and holes, which is achieved by the solar cell 100 according to the embodiment, is not exhibited.

Although an example of a single cell of the solar cell has been illustrated above, an array may be configured by electrically connecting a plurality of cells in series, in parallel, or in a combined manner of series connection and parallel connection. FIG. 4 illustrates an example of an array cell structure of the solar cell according to the embodiment. Specifically, this figure illustrates an example of an aspect as a two-series array of the solar cells.

A solar cell array 101 illustrated in the figure includes two solar cells 100 electrically connected in series. In the example illustrated in the figure, a single transparent substrate 1 is shared between the two solar cells 100, and one first electrode 2 serves as both a positive-side first electrode piece of the solar cell 100 on the left side and a negative-side first electrode piece of the solar cell 100 on the right side in the figure. Alternatively, the array may be configured by combining the individually prepared solar cells 100 without using a single member in common.

The electrical connection between the two solar cells 100 is made through the first electrode 2 located therebetween. A portion of the second electrode 5 on an upper surface of the first electrode 2 is partially removed, so as to prevent a short circuit between the second electrode 5 of the solar cell 100 on the left side and the n-type layer 3 of the solar cell 100 on the right side. Since the second electrode 5 of the solar cell 100 on the right side has no counterpart that may be short-circuited, the portion thereof on the upper surface of the first electrode 2 may not necessarily be removed as in the example illustrated in the figure.

The array of the solar cells according to the embodiment is not limited to the two-series array as in the example illustrated in the figure, and the number of single cells connected to form an array is not limited to two. The form of connection is not limited to series.

Next, details of the material and the like of each member of the solar cell will be described.

### <Transparent Substrate>

The transparent substrate is a plate-shaped substrate, which functions as a support substrate, and is made of a material having light transmission and insulation properties. As a material for the transparent substrate, an inorganic material such as alkali-free glass, quartz glass, white plate glass, chemically strengthened glass, or sapphire, or an organic material such as polyethylene (PE), polyethylene terephthalate (PET), polyethylene naphthalate (PEN), polyimide, polyamideimide, acryl, or a liquid crystal polymer may be used. Soda-lime glass is desirably used for the transparent substrate.

### <First Electrode>

The first electrode is an electrode on the n-type layer side, and having light transmission with respect to visible light. An oxide transparent conductive film (TCO film) is preferably used for the first electrode. The oxide transparent conductive film used for the first electrode is preferably one or more transparent conductive films selected from the group consisting of indium tin oxide (ITO), Al-doped zinc oxide (AZO), boron-doped zinc oxide (BZO), gallium-doped zinc oxide (GZO), indium-doped zinc oxide (IZO), aluminum gallium oxide (AGO), titanium-doped indium oxide (ITiO), indium gallium zinc oxide (IGZO), and hydrogen-doped indium oxide (In₂O₃).

A thickness of the first electrode is not particularly limited, but can be typically 1 nm or more and 2 μm or less. The thickness of the first electrode is preferably 50 nm or more and 1 μm or less.

The gap penetrating the first electrode may be, for example, a groove having a width of 10 μm or more and 100 μm or less.

<n-Type Layer>

The n-type layer is an n-type semiconductor layer. The n-type layer is located between the first electrode and the light absorption layer. A material having electron acceptability is used for the n-type semiconductor. The n-type layer is preferably a layer including an oxide layer or a sulfide layer. More specifically, the oxide layer used for the n-type layer is preferably a layer selected from the group consisting of Zn₍₁₋ₓ₎AₓO_{y} (A=Si, Ge, Sn; 0≤x≤1, 0<y≤4), Cu₍₂₋ₓ₎MₓO (M=Mn, Mg, Ca, Zn, Sr, Ba; 0≤x≤2), and Al₍₂₋ₓ₎GaₓO₃ (0≤x≤2). The sulfide layer used for the n-type layer is preferably a layer made of one or more sulfides selected from the group consisting of ZnₓIn₍₂₋₂ₓ₎S₍₃₋₂ₓ₎(0≤x≤1), ZnS, and InₓGa₍₁₋ₓ₎S (0≤x≤1). When Zn₍₁₋ₓ₎AₓO_{y} is used for the n-type layer, a Zn/A composition ratio is desirably in the range of 1 to 3, and more preferably 1.5 to 2.5.

A thickness of the n-type layer is preferably 5 nm or more and 100 nm or less. The thickness of the n-type layer is more preferably 10 nm or more and 50 nm or less. When the thickness of the n-type layer is 5 nm or more, a leakage current is less likely to occur even in the case of a poor coverage by the n-type layer. When the thickness of the n-type layer is 100 nm or less, the transmittance is good and the current is not hindered.

### <Light Absorption Layer>

The light absorption layer is a p-type semiconductor layer containing an inorganic material as a main component. The light absorption layer is located between the n-type semiconductor layer and the second electrode. Examples of the inorganic material which is a p-type semiconductor include an oxide of a metal containing Cu (copper) as a main component. Examples of the oxide of the metal containing Cu as the main component include cuprous oxide (Cu₂O) and composite oxides of cuprous oxide. The oxide of the metal containing Cu as the main component contains Cu (copper) in an amount of 60.0 atom % or more and 67.0 atom % or less and O (oxygen) in an amount of 32.5 atom % or more and 34.0 atom % or less. The composite oxide of cuprous oxide also includes metals other than Cu. The metal contained in the composite oxide of cuprous oxide is, for example, one or more metals selected from the group consisting of Sn, Sb, Ag, Li, Na, K, Cs, Rb, Al, Ga, In, Zn, Mg, and Ca, in addition to Cu. A band gap of the light absorption layer can be adjusted by blending one or more metals selected from the group consisting of Ag, Li, Na, K, Cs, Rb, Al, Ga, In, Zn, Mg, and Ca in addition to Cu. Examples of other materials include Cu(In,Ga)(S,Se)₂. Specific examples of this include CuInSn₂, CuInSe₂, CuGaS₂, CuGaSe₂, and mixed crystals thereof. In addition, there is also an example in which a part of Cu is replaced with Al.

The band gap of the light absorption layer is preferably 2.0 eV or more and 2.2 eV or less. When the band gap is in the range, sunlight can be efficiently used in both the top cell and the bottom cell in the multijunction solar cell in which the solar cell using Si for the light absorption layer is used as the bottom cell and the solar cell of the embodiment is used as the top cell. The light absorption layer may further contain Sn or Sb. Sn or Sb in the light absorption layer may be added to the light absorption layer or may be derived from the second electrode which is a p-electrode. High concentrations of Sn and Sb in the p-type light absorption layer increase defects, resulting in an increase in carrier recombination. Therefore, a total volume concentration of Sb and Sn in the light absorption layer is preferably 1.5×10¹⁹ atoms/cm³ or less.

The light absorption layer is, for example, a layer of an oxide represented by CuₐM_{b}O_{c}. M is one or more metals selected from the group consisting of Ag, Li, Na, K, Cs, Rb, Al, Ga, In, Zn, Mg, and Ca. Preferably, a, b, and c satisfy 1.80≤a≤2.01, 0.00≤b≤0.20, and 0.98≤c≤1.02, respectively. A composition ratio of the light absorption layer in the above example is a composition ratio of the entire light absorption layer. In addition, a compound composition ratio of the light absorption layer of the above example is preferably satisfied entirely in the light absorption layer.

A thickness of the light absorption layer is, for example, 1000 nm or more and 10000 nm or less. The thickness of the light absorption layer is preferably 6000 nm or less.

### <Second Electrode>

The second electrode may be, for example, a transparent conductive film, a metal film, or a stacked film of a transparent conductive film and a metal film.

Examples of the transparent conductive film include indium tin oxide (ITO), Al-doped zinc oxide (AZO), boron-doped zinc oxide (BZO), gallium-doped zinc oxide, fluorine-doped tin oxide (FTO), antimony-doped tin oxide (ATO), titanium-doped indium oxide (ITiO), indium zinc oxide (IZO), and indium gallium zinc oxide (IGZO). The transparent conductive film which may be used for the second electrode is not limited to these. The transparent conductive film may be a stacked film, and a film of tin oxide or the like may be included in the stacked film, in addition to the above-mentioned oxides.

Examples of the metal film include films of Mo, Au, and W. The metal film which may be used for the second electrode is not limited thereto.

The second electrode may be an electrode having metal provided on a surface of the transparent conductive film in dotted, line-shaped or mesh-shaped manner. At this time, the dotted, line-shaped, or mesh-shaped metal is arranged between the transparent conductive film and the light absorption layer. The dotted, line-shaped or mesh-shaped metal preferably has an aperture rate of 50% or more with respect to the transparent conductive film. The dotted, line-shaped, or mesh-shaped metal may include, for example, Mo, Au, and W, and is not particularly limited.

A thickness of the second electrode may be, for example, 1 nm or more and 1 μm or less. The thickness of the second electrode is desirably 5 nm or more and 100 nm or less.

### <Manufacturing Method>

The solar cell can be manufactured as follows.

A method for manufacturing a solar cell includes obtaining a first electrode, obtaining an n-type layer, obtaining a light absorption layer, and obtaining a second electrode. The transparent first electrode having a gap can be obtained by forming an oxide transparent conductive film on a transparent substrate and partially removing the oxide transparent conductive film. The n-type layer can be obtained by forming an n-type semiconductor film on the first electrode and the transparent substrate exposed through the gap, and removing a portion of the n-type semiconductor film in contact with a side surface of the first electrode located on one side of the gap and a part of a portion of the n-type semiconductor film in contact with an upper surface of the first electrode adjacent to the side surface. The light absorption layer can be obtained by forming an inorganic material film on the n-type layer, on the transparent substrate exposed through the gap, and on the first electrode exposed, and removing a portion of the inorganic material film in contact with each of the side surface and the upper surface. The second electrode can be obtained by forming another conductive film on the light absorption layer, on the transparent substrate exposed through the gap, and on the first electrode exposed. In obtaining the second electrode, of the other conductive film, a portion present on the first electrode may be partially removed.

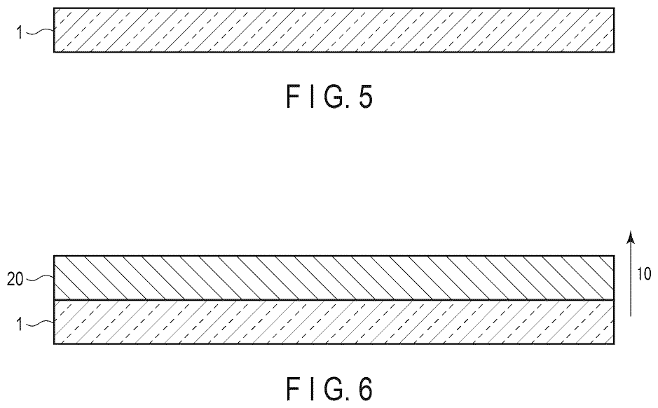

A specific example of the manufacturing method will be described with reference to FIGS. 5 to 12. Here, a method of manufacturing the two-series array illustrated in FIG. 4 will be exemplified.

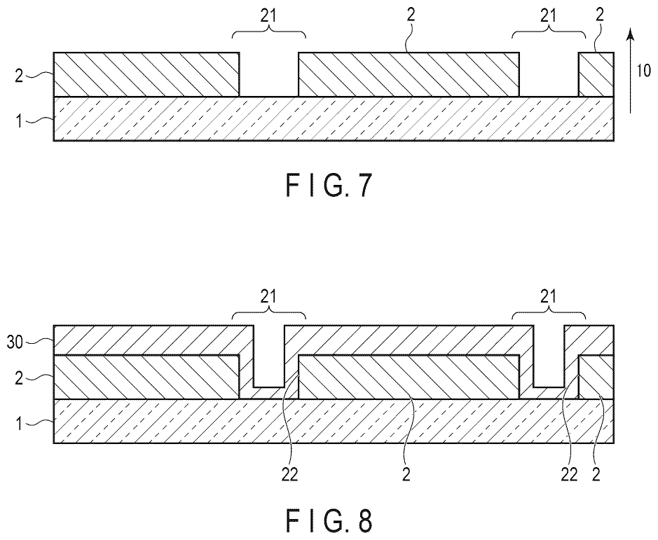

First, a transparent substrate 1 is prepared (FIG. 5). An oxide transparent conductive film 20 is formed on the transparent substrate 1 (FIG. 6). The oxide transparent conductive film 20 can be formed by sputtering using the material for the first electrode described above, for example. Thereafter, the oxide transparent conductive film 20 is partially removed, to obtain a first electrode 2 having a gap 21 (FIG. 7). In order to partially remove the oxide transparent conductive film 20, for example, patterning by chemical etching or laser etching is performed. Taking a thickness direction of the oxide transparent conductive film 20 as a first direction 10, the gap 21 penetrates the first electrode 2 in the first direction 10. For example, a groove having a width of several tens of μm, which penetrates the oxide transparent conductive film 20, is provided as the gap 21.

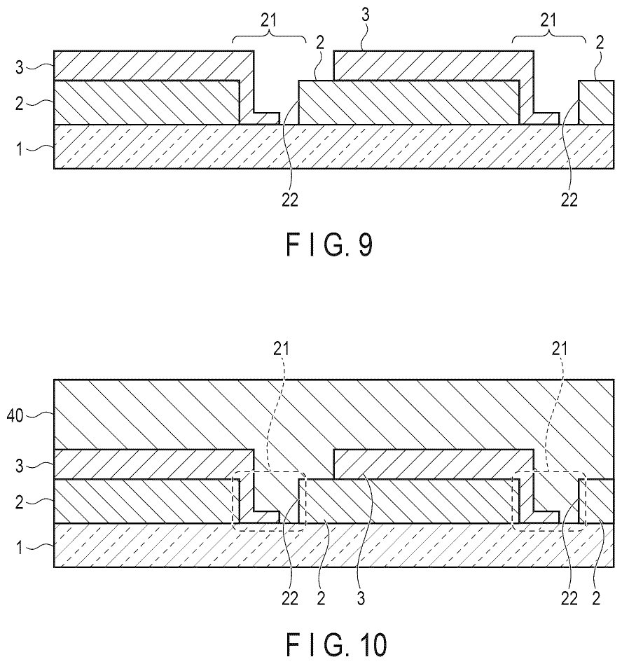

Next, an n-type semiconductor film 30 is formed on the first electrode 2 and the transparent substrate 1 exposed in the gap 21 (FIG. 8). For example, an n-type semiconductor material is deposited by chemical vapor deposition (CVD) under a condition of 500° C. or higher. Since a thickness of the n-type semiconductor film 30 is about several tens of nm and at most 100 nm, it is not realistic to fill the gap 21 having a width of several tens of μm with only the n-type semiconductor film 30. Thereafter, a portion of the n-type semiconductor film 30 in contact with a side surface 22 of the first electrode 2 located on one side of the gap 21 and a part of a portion of the n-type semiconductor film 30 in contact with an upper surface of the first electrode 2 adjacent to the side surface 22 are removed, to obtain the n-type layer 3 (FIG. 9). For the removal, for example, patterning by chemical etching or laser etching is performed.

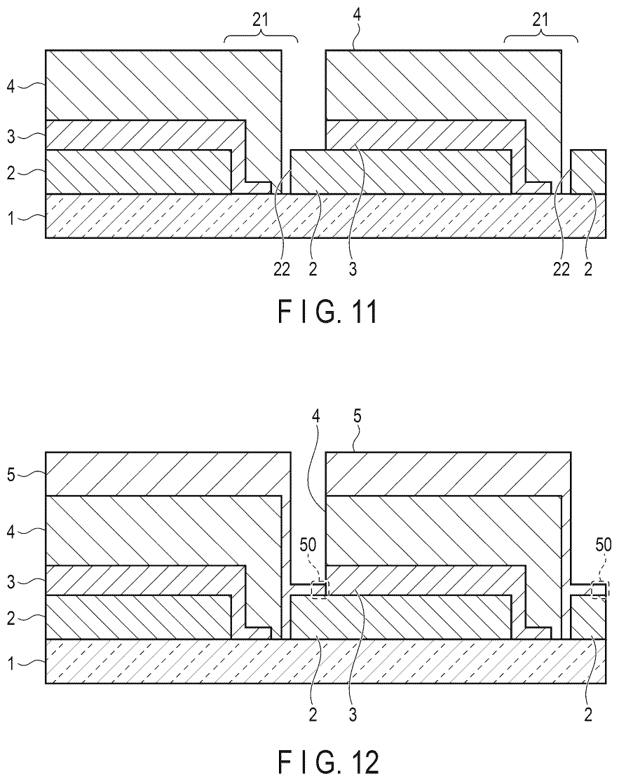

Next, an inorganic material film 40 is formed on the n-type layer 3, the transparent substrate 1 exposed in the gap 21, and exposed portions of the first electrode 2 (FIG. 10). For example, the film of the inorganic material constituting the light absorption layer described above is formed by electrodeposition, CVD, or sputtering. Thereafter, a portion of the inorganic material film 40 in contact with the side surface 22 of the first electrode 2 and a portion of the inorganic material film 40 in contact with the upper surface of the first electrode 2 adjacent to the side surface 22 are removed, to obtain the light absorption layer 4 (FIG. 11). For the removal, for example, patterning by chemical etching or laser etching is performed.

Subsequently, another conductive film is formed on the light absorption layer 4, the transparent substrate 1 exposed at the gap 21, and exposed portions of the first electrode 2, to obtain the second electrode 5 (FIG. 12). The other conductive film may be formed by CVD using the material for the second electrode described above, for example. In the case of manufacturing an array as exemplified, in order to eliminate a short circuit between the second electrode 5 and the n-type layer 3, portions of the second electrode 5 surrounded by a broken line 50 are removed by performing patterning by, for example, chemical etching or laser etching. Of the two portions surrounded by the broken line 50, removal of just the left portion is possible. When both of the two portions surrounded by the broken line 50 are removed, a two-series array having a structure similar to that of the solar cell array 101 illustrated in FIG. 4 can be obtained.

In the above method, when patterning in each stage is performed, the portion to be removed by etching is the gap 21 having a wide width and the portion adjacent thereto. Since there is a spatial margin with respect to the member not to be removed, for example, a wider clearance can be taken at sections irradiated by the laser when laser etching is performed. In the manufacture of a conventional solar cell array, for example, there is a case where a laser is applied to remove a film at a deep portion between the members not to be removed, but at this time, a portion of the light absorption layer adjacent to the irradiation laser may become heated, forming a defect. Due to defect formation, a current which can flow through the light absorption layer is reduced, whereby the conversion efficiency may be reduced.

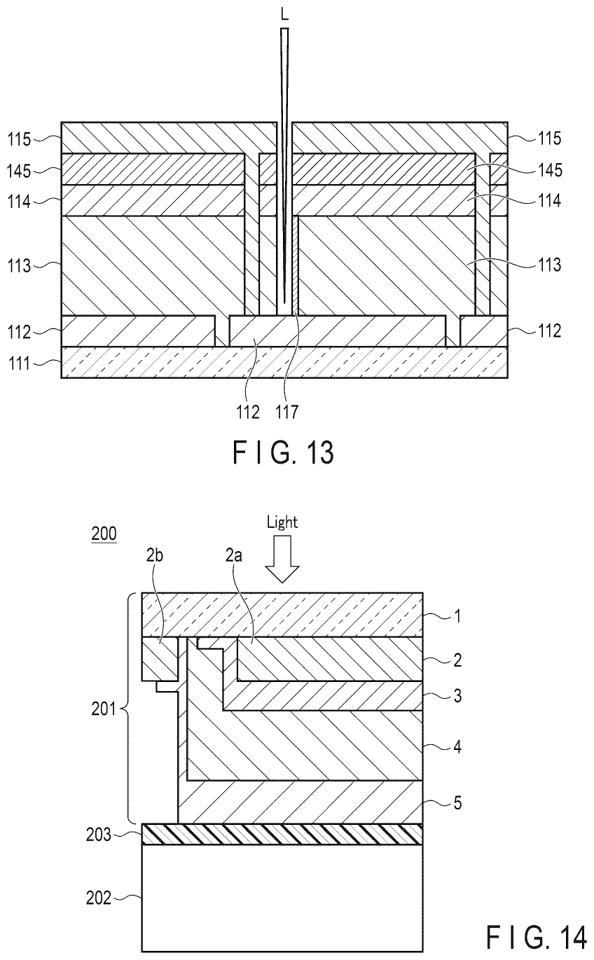

FIG. 13 illustrates an example of a process in manufacturing the conventional solar cell. This figure illustrates an example of manufacturing a two-series array of solar cells having a structure similar to that of the conventional solar cell illustrated in FIG. 2. After a p-electrode 112, a light absorption layer 113, an n-type layer 114, and an n-electrode 115 are sequentially stacked by repeating film formation and patterning on a substrate 111, connection is cut between cells of the solar cells other than series connection by the p-electrode 112 located at a lower portion, to partition the single cell. Specifically, for example, etching with the laser L is performed to remove the members on top of the p-electrode 112 while leaving the p-electrode, thereby sculpting a narrow groove. Here, since the p-electrode 112 is located in a deep portion of the narrow groove, a distance between a side surface of the groove and the laser L is likely to be short, and for example, a surface temperature of a side surface of the light absorption layer 113 may become high. A defect region 117 is formed on the side surface of the light absorption layer 113 by heat, and the current which can flow decreases.

### Second Embodiment

According to a second embodiment, a multijunction solar cell is provided. The multijunction solar cell includes a first solar cell, and a second solar cell that includes a second light absorption layer having a band gap smaller than a band gap of a first light absorption layer of the first solar cell. The first solar cell is the solar cell according to the first embodiment. The second electrode is a transparent electrode.

FIG. 14 shows a cross-sectional conceptual view of an example of such a multijunction solar cell 200. The multijunction solar cell 200 illustrated in the figure includes a first solar cell 201 and a second solar cell 202. The first solar cell 201 is the solar cell according to the first embodiment. The first solar cell 201 is located on a light incident side of the multijunction solar cell 200, and is in contact with the second solar cell 202 at a surface on the second electrode 5 (p-electrode) side. In the multijunction solar cell 200, a transparent electrode is used not only for a first electrode 2 (n-electrode) of the first solar cell 201 but also for the second electrode 5. As a result, among light incident from the first electrode side, light which is not absorbed by a light absorption layer 4 can be transmitted through the second electrode 5 and incident on the second solar cell 202. Therefore, electric power can be generated by the second solar cell 202 using incident light which has not been used by the first solar cell 201. The first solar cell 201 and the second solar cell 202 can be joined via, for example, an intermediate adhesive layer 203.

The second solar cell 202 may be, for example, an Si solar cell.

A band gap of a light absorption layer of the second solar cell 202 is smaller than a band gap of the light absorption layer 4 of the first solar cell 201. The multijunction solar cell of the embodiment also includes a solar cell in which three or more solar cells are joined. When the first solar cell 201 including the light absorption layer having a wide band gap is used as a top cell and the second solar cell 202 including the light absorption layer having a narrow band gap is used as a bottom cell, transmission with respect to a wavelength contributing to the power generation on the bottom cell side is high in the top cell, and thus an amount of power generation on the bottom cell side is high. Therefore, excellent conversion efficiency can be exhibited.

Since the second solar cell 202 does not include a glass substrate, the multijunction solar cell 200 includes only one glass substrate (a transparent substrate 1 of the first solar cell 201). In addition, since the intermediate layer between the first solar cell 201 and the second solar cell 202 is just the intermediate adhesive layer 203, an amount of light reaching the second solar cell 202 via the first solar cell 201 is large. Therefore, the multijunction solar cell 200 is lightweight, and is excellent in conversion efficiency because the solar cell of the first embodiment is used.

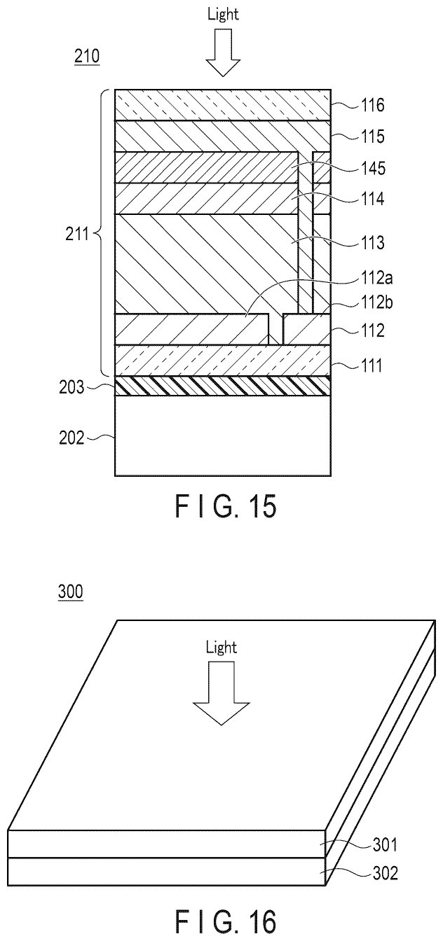

FIG. 15 shows a cross-sectional conceptual view of an example of a multijunction solar cell using a conventional substrate type solar cell as the top cell. A multijunction solar cell 210 illustrated in the figure includes a first solar cell 211 and a second solar cell 202. The first solar cell 211 has the same structure as that of the solar cell 110 of the conventional example illustrated in FIG. 2. Therefore, the first solar cell 211 includes a total of two glass substrates, i.e., a sealing substrate on an n-electrode 115 side in addition to a substrate 111 on a p-electrode 112 side. Therefore, although the second solar cell 202 does not include a glass substrate, the number of glass substrates included in the multijunction solar cell 210 is two, which requires more materials and increases the thickness and weight.

A band gap of a light absorption layer of the second solar cell 202 may be, for example, 1.0 eV or more and 1.6 eV or less. Specific examples of the light absorption layer of the second solar cell 202 may include one or more compound semiconductor layers of CIGS-based, CIT-based, and CdTe-based materials having a high In content ratio, or crystalline silicon.

### Third Embodiment

According to a third embodiment, a solar cell module is provided. The solar cell module includes the solar cell according to the first embodiment. Hence, the solar cell module is excellent in conversion efficiency.

FIG. 16 shows a perspective conceptual view of an example of such a solar cell module 300. The solar cell module 300 illustrated in the figure is a solar cell module in which a first solar cell module 301 and a second solar cell module 302 are stacked. The first solar cell module 301 is located on a light incident side, and includes the solar cell of the first embodiment. For the second solar cell module 302, the second solar cell 202 is preferably used.

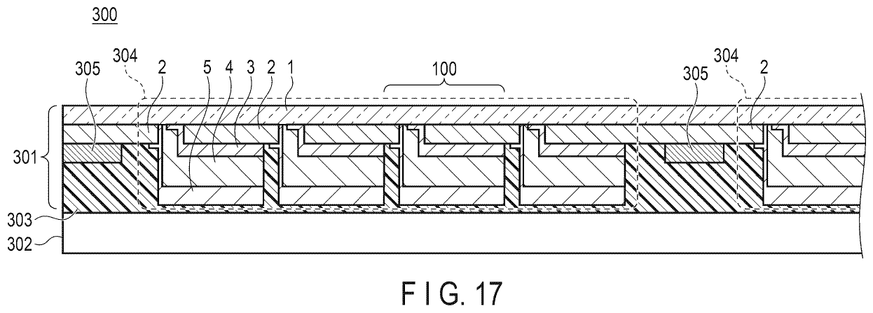

FIG. 17 shows a cross-sectional conceptual view of the example of the solar cell module 300. In this figure, the structure of the first solar cell module 301 is illustrated in detail, and details of the structure of the second solar cell module 302 are not illustrated. For the second solar cell module 302, the structure of the solar cell module is appropriately selected according to the light absorption layer and the like of the solar cell to be used. The first solar cell module 301 and the second solar cell module 302 are stacked via a sealing layer 303 also serving as an intermediate adhesive layer. The sealing layer 303 fills a gap between the first solar cell module 301 and the second solar cell module 302.

The solar cell module 300 of the example illustrated in the figure includes a plurality of submodules 304 indicated by surrounding with broken lines, in which a plurality of solar cells 100 are arranged in the lateral direction and electrically connected in series, and the submodules 304 are electrically connected in parallel or in series. The adjacent submodules 304 may also be electrically connected by a bus bar 305. For example, in the example illustrated in the figure, a group of submodules 304 connected in series in the lateral direction of the figure is connected in parallel with another group of submodules (not illustrated) adjacent in the depth direction of the figure via the bus bar 305.

Each submodule 304 includes a plurality of solar cells 100 sharing one transparent substrate 1. The transparent substrate 1 may also be shared among a plurality of submodules. Similarly to the two-series array illustrated in FIG. 4, for example, the two adjacent solar cells 100 can be connected in series by electrically connecting the first electrode 2 (n-electrode) of one solar cell 100 on the transparent substrate 1 side to the second electrode 5 (p-electrode) on an opposite side of the adjacent solar cell 100. Each of these solar cells 100 can have a structure similar to that of the solar cell according to the first embodiment. However, similarly to the multijunction solar cell according to the second embodiment, the second electrode 5 is a transparent electrode. The sealing layer 303 also has translucency. Therefore, incident light can be taken into the first solar cell module 301 from the transparent substrate 1 side, and light that has not been absorbed by the first solar cell module 301 can be taken into the second solar cell module 302.

In the first solar cell module 301, the electrical connection between the submodules 304 by the bus bars 305 is preferably configured appropriately in view of adjustment of an output voltage between the first solar cell module 301 and the second solar cell module 302.

### Fourth Embodiment

According to a fourth embodiment, a solar power generation system is provided. The solar power generation system includes the solar cell module according to the third embodiment. Therefore, the solar power generation system is excellent in conversion efficiency.

The solar cell module according to the third embodiment can be used as a generator configured to generate electric power in the solar power generation system of the fourth embodiment. The solar power generation system according to the embodiment is configured to generate electric power using a solar cell module, and specifically includes a solar cell module configured to generate electric power, a power conversion unit for converting generated electricity, and a storage unit for storing generated electricity or a load for consuming generated electricity.

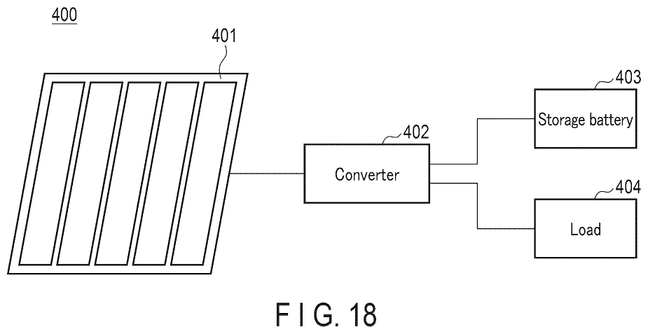

FIG. 18 shows a conceptual configuration view of an example of a solar power generation system 400. The solar power generation system illustrated in the figure includes a solar cell module 401, a converter 402, a storage battery 403, and a load 404. Either the storage battery 403 or the load 404 may be omitted. The load 404 may be configured to be able to use electric energy stored in the storage battery 403. The converter 402 is an apparatus including a circuit or an element configured to perform electrical power conversion such as transformation or DC-AC conversion, such as a DC-DC converter, a DC-AC converter, or an AC-AC converter. As the configuration of the converter 402, a suitable configuration may be adopted according to the generated voltage and the configurations of the storage battery 403 and the load 404.

A solar cell included in the solar cell module 401 generates electric power, and the electric energy is converted by the converter 402 and stored in the storage battery 403 or consumed by the load 404. The solar cell module 401 is preferably provided with a sunlight tracking drive apparatus for constantly directing the solar cell module 401 toward the sun, a light collector for collecting sunlight, an apparatus for improving power generation efficiency, or the like.

The solar power generation system 400 is preferably used in immovable properties such as a residence, a commercial facility, and a factory, or used in movable properties such as a vehicle, an aircraft, and an electronic device. By using the solar cell module according to the third embodiment having excellent conversion efficiency as the solar cell module 401, an increase in amount of power generation is expected.

### EXAMPLES

Hereinafter, the present invention will be described more specifically based on Examples, but the present invention is not limited to the following Examples.

### Manufacture of Solar Cell

### Example 1

In the following manner, a solar cell having the structure illustrated in FIG. 1 was produced. The solar cell is an example of a light transmitting thin film type Cu₂O solar cell.

An AZO transparent conductive film was deposited on a glass substrate to form an oxide transparent conductive film, and then a part of the oxide transparent conductive film was removed by patterning to provide a gap penetrating the film. The patterning was performed by resist application and wet etching. Thus, an n-electrode (first electrode) divided into two electrode pieces was obtained. The gap was provided along a position close to one side of the conductive film, so that one n-electrode piece had a significantly larger area than the other n-electrode piece.

Next, an n-type semiconductor film was formed by depositing Ga₂O₃ by a chemical vapor deposition (CVD) method at 560° C. Thereafter, of the n-type semiconductor film, a portion on the n-electrode piece with a smaller area and a portion adjacent to the side surface of that n-electrode piece in the gap were removed by patterning. The patterning was performed by resist application and wet etching. Thus, an n-type layer was obtained.

Subsequently, a Cu₂O film was formed by a CVD method and a sputtering method in an argon gas atmosphere, with heating at 500° C. Thereafter, of the Cu₂O film, a portion on the n-electrode piece with a smaller area and a portion adjacent to the side surface of that n-electrode piece in the gap were removed by patterning. The patterning was performed by laser scribing. Thus, a light absorption layer was obtained.

Subsequently, an antimony-doped tin oxide (ATO) transparent conductive film and an indium-doped tin oxide (ITO) transparent conductive film were sequentially formed as p-electrodes to obtain a second electrode.

As an energization path for extracting electric power, an electrode lead was connected to each n-electrode piece.

### Comparative Example 1

In the following manner, a solar cell having the structure illustrated in FIG. 2 was produced.

An ITO transparent conductive film was deposited on a glass substrate to form an oxide transparent conductive film, and then processing of removing a part of the oxide transparent conductive film was performed to provide a gap penetrating the film. The patterning was performed by resist application and wet etching. Thus, a p-electrode divided into two electrode pieces was obtained. The gap was provided along a position close to one side of the conductive film, so that one p-electrode piece had a significantly larger area than the other p-electrode piece.

Next, a Cu₂O film was formed by a CVD method and a sputtering method in an argon gas atmosphere, with heating at 500° C. Thus, a light absorption layer was obtained.

Then, an n-type semiconductor film was formed by depositing Ga₂O₃ by the CVD method at 560° C. Thereafter, a buffer layer was formed by depositing ZTO. Thus, an n-type layer and a buffer layer were obtained.

Subsequently, the buffer layer, the n-type layer, and the light absorption layer were partially removed by patterning to provide a groove penetrating the films. Laser etching was used for the patterning. The groove was provided along a position close to one side of the stack.

Thereafter, an AZO transparent conductive film was formed to obtain an n-electrode.

Finally, a glass substrate was stacked as a sealing substrate on the n-electrode.

As an energization path for extracting electric power, an electrode lead was connected to each p-electrode piece.

### Comparative Example 2

In the following manner, a solar cell having the structure illustrated in FIG. 3 was produced.

An AZO transparent conductive film was deposited on a glass substrate to form an oxide transparent conductive film, and then a part of the oxide transparent conductive film was removed by patterning to provide a groove penetrating the film. The patterning was performed by resist application and wet etching. Thus, an n-electrode divided into two electrode pieces was obtained. The gap was provided along a position close to one side of the conductive film, so that one n-electrode piece had a significantly larger area than the other n-electrode piece.

Next, an n-type semiconductor film was formed by depositing Ga₂O₃ by the CVD method at 560° C. Thus, an n-type layer was obtained.

Subsequently, a Cu₂O film was formed by a CVD method and a sputtering method in an argon gas atmosphere, with heating at 500° C. Thus, a light absorption layer was obtained.

Subsequently, the light absorption layer and the n-type layer were partially removed by patterning to provide a groove penetrating the films. Laser etching was used for the patterning. The groove was provided along a position close to one side of the stack.

Thereafter, an antimony-doped tin oxide (ATO) transparent conductive film and an indium-doped tin oxide (ITO) transparent conductive film were sequentially formed as p-electrodes to obtain a second electrode.

As an energization path for extracting electric power, an electrode lead was connected to each n-electrode piece.

### <Performance Evaluation>

The conversion efficiency of each of the solar cells produced in Example 1, Comparative Example 1, and Comparative Example 2 was measured as follows.

First, an electric power supply, an ammeter, and simulated sunlight (1 kW/m²) were prepared. The electric power supply, the ammeter, and the solar cell were electrically connected in series. The voltage (V) of the power supply was varied in a state where the solar cell was irradiated with simulated sunlight, and a change in current density (mA/cm²) at that time was acquired. A voltage-power (mW/cm²) curve was calculated from the acquired current-voltage characteristics, and the maximum power (mW/cm²) in the curve was recorded as conversion efficiency (%).

As a result of the above measurement, it was found that the solar cell produced in Example 1 can achieve higher conversion efficiency than the solar cells produced in Comparative Example 1 and Comparative Example 2.

According to at least one embodiment and example described above, a solar cell is provided. The solar cell includes a transparent first electrode including a penetrating gap, an n-type layer, a light absorption layer that contains an inorganic material, and a second electrode. The n-type layer is present between the first electrode and the light absorption layer. The light absorption layer is present between the n-type layer and the second electrode. The n-type layer, the light absorption layer, and the second electrode are each partially included in the gap, and a part of the n-type layer, a part of the light absorption layer, and inside the gap, a part of the second electrode are arranged in this order. The above solar cell can exhibit excellent conversion efficiency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solar cell comprising:
a transparent first electrode;
an n-type layer;
a light absorption layer that contains an inorganic material; and
a second electrode,
the n-type layer being present between the first electrode and the light absorption layer, and the light absorption layer being present between the n-type layer and the second electrode,
the first electrode having a gap penetrating the first electrode, and
the n-type layer, the light absorption layer, and the second electrode each being partially included in the gap, and a part of the n-type layer, a part of the light absorption layer, and a part of the second electrode being arranged in this order in the gap.

2. The solar cell according to claim 1, wherein the light absorption layer contains cuprous oxide.

3. The solar cell according to claim 1, wherein the second electrode contains a metal material or an alloy material.

4. A multijunction solar cell comprising:
a first solar cell; and
a second solar cell that includes a second light absorption layer having a band gap smaller than a band gap of a first light absorption layer of the first solar cell,
the first solar cell being the solar cell according to claim 1, and the second electrode being a transparent electrode.

5. The multijunction solar cell according to claim 4, wherein the first solar cell is joined to the second solar cell at a surface on the second electrode side.

6. A solar cell module comprising the solar cell according to claim 1.

7. A solar power generation system comprising the solar cell module according to claim 6.

8. A method for manufacturing a solar cell, the solar cell comprising:
a transparent first electrode;
an n-type layer;
a light absorption layer that contains an inorganic material; and
a second electrode,
the n-type layer being present between the first electrode and the light absorption layer, and the light absorption layer being present between the n-type layer and the second electrode,
the first electrode having a gap penetrating the first electrode, and
the n-type layer, the light absorption layer, and the second electrode each being partially included in the gap, and a part of the n-type layer, a part of the light absorption layer, and a part of the second electrode being arranged in this order in the gap,
the method comprising:
forming an oxide transparent conductive film on a transparent substrate;
obtaining the first electrode by partially removing the oxide transparent conductive film;
forming an n-type semiconductor film on the first electrode and the transparent substrate exposed through the gap;
obtaining the n-type layer by removing a portion of the n-type semiconductor film in contact with a side surface of the first electrode located on one side of the gap and a part of a portion of the n-type semiconductor film in contact with an upper surface of the first electrode adjacent to the side surface;
forming an inorganic material film on the n-type layer, on the transparent substrate exposed through the gap, and on the first electrode exposed;
obtaining the light absorption layer by removing portions of the inorganic material film in contact with the side surface and the upper surface; and
obtaining the second electrode by forming another conductive film on the light absorption layer, on the transparent substrate exposed through the gap, and on the first electrode exposed.
